(19) United States
(12) Patent Application Publication
(10) Pub. No.: US 2005/0275008 A1
(43) Pub. Date: Dec. 15, 2005

(54) [NON-VOLATILE MEMORY AND FABRICATION THEREOF]

(76) Inventor: Erh-Kun Lai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,021

(22) Filed: Jun. 14, 2004

(51) Int. Cl. G11C 11/34

(52) U.S. Cl. 257/314

(57) ABSTRACT

A method for fabricating a non-volatile memory having two bits per cell is described. In the method, a substrate having a gate dielectric layer and a linear conductor thereon is provided, and a trapping layer is formed on the substrate and two sidewalls of the linear conductor. Two conductive spacers are then formed on the two sidewalls of the linear conductor, interposed by the trapping layer. The linear conductor will be defined into a gate, with two patterned conductive spacers on the two sidewalls thereof. The trapping layer under the two patterned conductive spacers serves as two data storage sites.

### BACKGROUND OF INVENTION

1. Field of the Invention

The present invention relates to a semiconductor device and a method for fabricating the same. More particularly, the present invention relates to a non-volatile memory device and a method for fabricating the same.

2. Description of the Related Art

Currently, programmable and erasable non-volatile memory devices include EEPROM, flash EEPROM, and nitride read-only memory, etc., wherein EEPROM-type devices store data in floating gates and nitride read only memory in nitride trapping layers. A conventional nitride read only memory cell includes an oxide/nitride/oxide (ONO) composite layer between substrate and gate, and can store two bits in two portions of the nitride layer near the source/drain. However, since the rest of the nitride layer between the two data storage sites also traps a small amount of charges during operation, the threshold voltage (V_{T}) of the channel is changed after long-term use even causing a failing memory cell. Therefore, discrete charge trapping layer structures are proposed.

U.S. Pat. No. 6,248,633 to Ogura et al. discloses a method for fabricating a discrete nitride read only memory device, wherein two separate control lines are formed as spacers beside a word gate over two ONO trapping layers, and the gate insulator under the word gate and between the two ONO trapping layers is an oxide layer. The word gate is connected with a word line that crosses over the control lines. However, since the control lines have to be applied with a voltage during the operation, additional electrical connection and a control line decoder are needed for the control lines.

U.S. Pat. No. 6,670,240 to Ogura et al. discloses another method for fabricating a discrete nitride read only memory device. In the method, two L-shaped trapping layers are formed on two sidewalls of a trench, and gate oxide and a central gate are defined between the two trapping layers after polysilicon is filled into the trench for forming two side gates on the two L-shaped trapping layers. However, since forming the trench and defining the central gate each requires a lithography process, the method suffers from a complicated fabricating process.

### SUMMARY OF INVENTION

In view of the foregoing, this invention provides a method for fabricating a non-volatile memory having multi-bits per cell.

This invention also provides a simpler method for fabricating a non-volatile memory having multi-bits per cell, which utilizes self-alignment mechanism in definition of the gate and the data storage regions to simplify the fabricating process.

This invention further provides a non-volatile memory device having multi-bits per cell that can be fabricated by using the method of this invention.

This invention also provides a non-volatile memory array that is based on the non-volatile memory device of this invention.

The method for fabricating a non-volatile memory of this invention is described as follows. A linear conductor is formed on a substrate interposed by a gate dielectric layer, and a trapping layer is formed on the substrate and two sidewalls of the linear conductor. Two conductive spacers are then formed on the two sidewalls of the linear conductor, interposed by the trapping layer. A buried drain is then formed in the substrate outside each conductive spacer, and a buried drain insulator is formed on the buried drain. Thereafter, a conductive layer is formed over the substrate, and the conducive layer, the linear conductor and the two conductive spacers are patterned, in a direction different from the orientation of the buried drain, to form a word line and a gate electrically connected with the word line. The gate is patterned from the linear conductor, and the trapping layer under the two patterned conductive spacers serves as two discrete data storage regions.

The non-volatile memory device of this invention includes a substrate, a gate dielectric layer and a gate thereon, two L-shaped trapping layers on two sidewalls of the gate and the substrate, two conductive spacers, two doped regions and a word line. The two conductive spacers are disposed on the two sidewalls of the gate, separated from the gate and the substrate by the L-shaped trapping layers. The two doped regions as a source and a drain, respectively, are located in the substrate beside the conductive spacers. The word line is disposed over the substrate, contacting with the conductive spacers and the top of the gate.

The non-volatile memory array of this invention includes a substrate, multiple gate structures arranged in rows and columns, buried drains and word lines. Each gate structure includes a gate dielectric layer and a gate thereon, two L-shaped trapping layers on sidewalls of the gate and the substrate, and two conductive spacers on the sidewalls of the gate separated from the gate and the substrate by the trapping layers. Each buried drain is disposed between two columns of gate structures. Each word line is disposed over the substrate, contacting with the two conductive spacers and the top of the gate of each of the gate structures in one row.

Since the trapping layer is formed along the sidewalls of the linear conductor, the gate and the two discrete data storage regions are form in a self-aligned manner. Therefore, the fabricating process can be simplified. Moreover, since the conductive spacers above the data storage regions are electrically connected to the word line, no separate control line is needed. Therefore, additional electrical connection and control line decoder are not required.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A, 2-7 and 8A illustrate a process flow of fabricating a non-volatile memory having two bits per cell according to a preferred embodiment of this invention in a cross-sectional view.

FIGS. 1B and 8B illustrate top views of the structures corresponding to FIGS. 1A and 8A, respectively, while FIGS. 1A and 8A are cross-sectional views of the structures along line I-I′. FIGS. 8A and 8B further illustrate a nonvolatile memory array according to the preferred embodiment of this invention.

### DETAILED DESCRIPTION

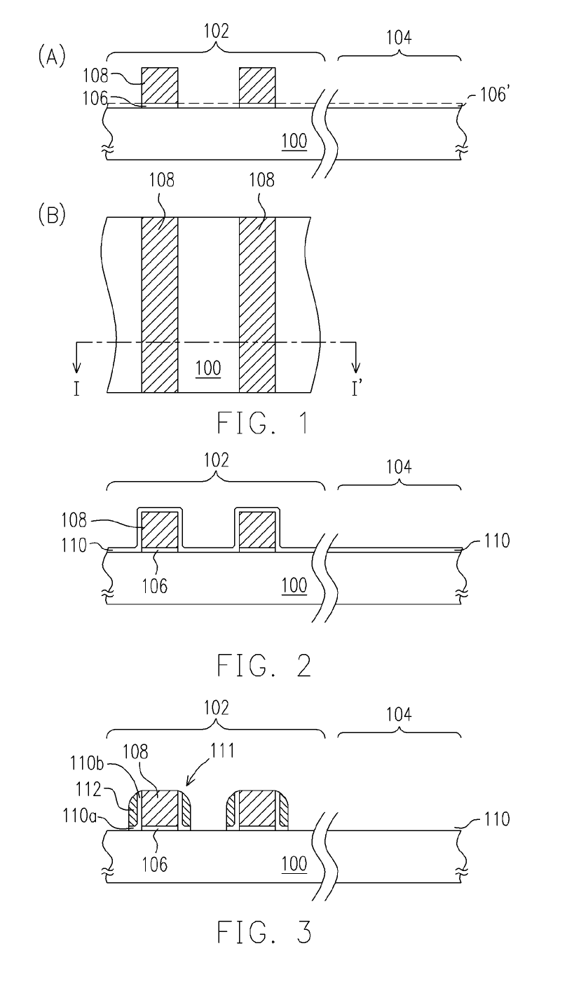

The preferred embodiment of this invention is described as follows referring to FIGS. 1-8, wherein only FIGS. 1 and 8 show simultaneously a top view and a cross-sectional view along line I-I′.

Referring to FIGS. 1A and 1B, a substrate 100, such as, a single-crystal silicon substrate, is provided, including a memory area 102 and a peripheral area 104 for forming peripheral devices. Then, a gate dielectric layer 106, such as, a gate oxide layer, is formed on the substrate 100, and linear conductors 108 that will be defined into gates latter are formed on the gate dielectric layer 106 in the memory area 102. The material of the linear conductors 108 is, for example, doped polysilicon. The etching process for defining the linear conductors 108 may be conducted so that the gate dielectric layer 106 not covered by the linear conductors 108 is also removed. Alternatively, the etching process is stopped on the gate dielectric layer 106, as indicated by the dashed-line layer 106′.

Referring to FIG. 2, a substantially conformal trapping layer 110 is formed over the substrate 100 covering the linear conductors 108. The trapping layer 110 is preferably an ONO composite layer, wherein the sandwiched nitride layer has numerous charge-trapping sites and the top and bottom oxide layers have high energy barrier preventing the trapped charges from escaping. Alternatively, when the gate dielectric layer 106 is an oxide layer and the etching process for defining the linear conductors 108 is stopped on the oxide layer, as indicated by the dashed-line layer 106′ in FIG. 1, the trapping layer 110 can be an NO composite layer that constitutes an ONO composite layer together with the oxide layer.

Referring to FIG. 3, two conductive spacers 112 are formed on the two sidewalls of each linear conductor 108, interposed by the vertical portions 110b of the trapping layer 110. The two conductive spacers 112 are also separated from the substrate 100 by two lateral portions 110a of the trapping layer 110. In addition, the material of the conductive spacers 112 is doped polysilicon, for example. Thereafter, the trapping layer 110 not covered by the conductive spacers 112 is removed leaving multiple L-shaped trapping layers, each of which includes a vertical portion 110b and a lateral portion 110a of the trapping layer 110, so as to form linear stacked structures 111. Each linear stacked structure 111 includes a gate dielectric layer 106, a linear conductor 108 on the gate dielectric layer 106, two conductive spacers 112 on the two sidewalls of the linear conductor 108, and a trapping layer 110a/b between the conductive spacers 112 and the linear conductor 118 and between the conductive spacers 112 and the substrate 100. Each linear stacked structure 111 will be defined into multiple stacked gate structures latter.

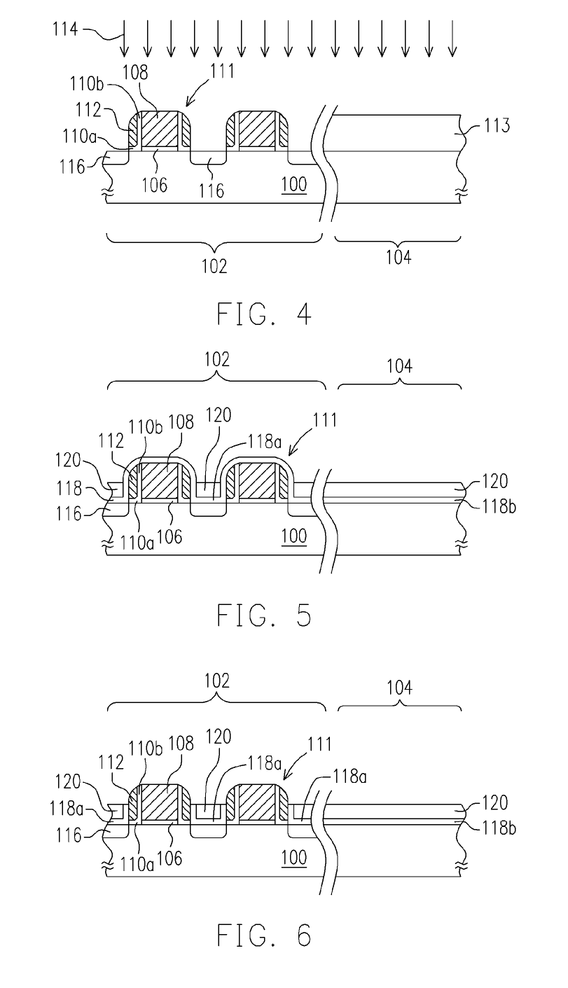

Referring to FIG. 4, a mask layer 113, such as, a photoresist layer 113, is formed covering the peripheral area 104 but exposing the whole memory area 102. Ion implantation 114 is then performed using the mask layer 113, the conductive spacers 112 and the linear conductors 108 as a mask, so as to form linear buried drains 116 between the linear stacked structures 111. Thereafter, n-wells and p-wells (not shown) can be formed in the peripheral area 104, which is a part of ordinary CMOS process.

Referring to FIG. 5, an insulating layer 118 is formed over the substrate 100 in the memory area 102 and the peripheral area 104, wherein the portions of the insulating layer 118 on the buried drains 116 serve as buried drain insulators 118a, and the portion of the insulating layer 118 in the peripheral area 104 serves as a gate insulator 118b of peripheral devices. The insulating layer 118 may be a thermal oxide layer formed with a thermal oxidation process, which also produce silicon oxide on the linear conductors 108 and the conductive spacers 112 when the linear conductors 108 and the conductive spacers 112 both include polysilicon, as shown in FIG. 5. Moreover, when the insulating layer 118 is formed with a thermal oxidation process, the thickness of the buried drain insulators 118a is about 2-3 times the thickness of the gate insulator 118b in the peripheral area 104 due to high doping concentration of the buried drains 116.

Thereafter, a protective layer 120 is formed on the buried drain insulators 118a and the gate insulator 118b of the peripheral devices. The protective layer 120 is preferably a bottom anti-reflection coating (BARC), which is preferably applied in the form of material solution with a spin-on method. Since the BARC material and the insulating layer 118 of silicon oxide both have high etching selectivity to polysilicon, the linear conductors 108 and the conductive spacers 112 are little damaged.

Referring to FIG. 6, the portions of the insulating layer 118 on the linear conductors 108 and the conductive spacers 112 are removed using the protective layer 120 as a mask, so that the surfaces of the linear conductors 108 and the conductive spacers 112 are exposed.

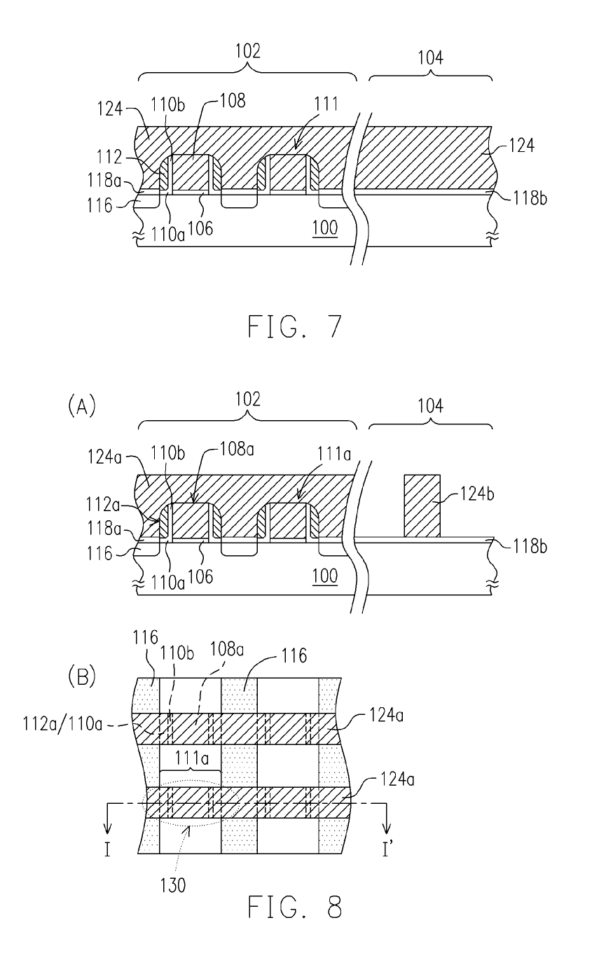

Referring to FIG. 7, a conductive layer 124, such as, a doped polysilicon layer, is formed over the whole substrate 100. Since the top surfaces of the linear conductors 108 and the conductive spacers 112 have been exposed, the conductive layer 124 directly contacts with the top of the linear conductors 108 and the conductive spacers 112.

Referring to FIGS. 8A and 8B, the conductive layer 124 in the memory area 102 and the linear stacked structures 111 are patterned, perpendicular to the buried drain 116, to form word lines 124a and stacked gate structures 111a, respectively. Meanwhile, the conductive layer 124 in the peripheral area 104 is patterned into gates 124b of the peripheral devices. Each stacked gate structure 111a includes a gate dielectric layer 106, a gate 108a on the gate dielectric layer 106, two L-shaped trapping layers 110a/b, and two conductive spacers 112a on the two sidewalls of the gate 108a. The trapping layers 110a/b are between the two conductive spacers 112a and the gate 108a and between the two conductive spacers 112a and the substrate 100, wherein the lateral trapping layers 110a between the two conductive spacers 112a and the substrate 100 serve as two data storage sites. Moreover, a stacked gate structure 111a, the substrate 100 under the stacked gate structure 111a and the buried drains 116 beside the stacked gate structure 111a together constitute a non-volatile memory cell 130, which has two data storage sites 110a and is therefore capable of storing two bits.

FIGS. 8A and 8B further illustrate a non-volatile memory array according to the preferred embodiment of this invention. Referring to FIGS. 8A and 8B, the non-volatile memory array includes a substrate 100, multiple gate structures 111a arranged in rows and columns, buried drains 116 and word lines 124a. Each gate structure 111a includes a gate dielectric layer 106 and a gate 108a thereon, two L-shaped trapping layers 110a/b on the sidewalls of the gate 108a and the substrate 100, and two conductive spacers 112a on the sidewalls of the gate 108a separated from the gate 108a and the substrate 100 by the trapping layers 110a/b. Each buried drain 116 is disposed between two columns of gate structures 111a. Each word line 124a is disposed over the substrate 100, contacting with the two conductive spacers 112a and the top of the gate 108a of each of the gate structures 11a in one row.

Since the trapping layer 110 is defined using the two conductive spacers 112 on the sidewalls of each linear conductor 108 as a mask, the gates 108a/112a and the two discrete data storage regions 110a are form in a self-aligned manner. Therefore, the fabricating process can be simplified. Moreover, since the conductive spacers 112a above the data storage regions 110a are electrically connected to the word lines 124a, no separate control line is needed. Therefore, additional electrical connection and control line decoder are not required.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1-20. (canceled)

21. A non-volatile memory device, comprising:
a substrate;
a gate dielectric layer on the substrate;
a gate on the gate dielectric layer;
two L-shaped trapping layers on sidewalls of the gate and on the substrate;
two conductive spacers on the sidewalls of the gate, separated from the gate and
the substrate by the L-shaped trapping layers;
two doped regions in the substrate beside the conductive spacers; and
a word line over the substrate, contacting with the conductive spacers and top of the gate.

22. The non-volatile memory device of claim 21, wherein each L-shaped trapping layer comprises an ONO composite layer.

23. The non-volatile memory device of claim 21, wherein the gate dielectric layer comprises an oxide layer.

24. The non-volatile memory device of claim 21, wherein the word line, the gate and the conductive spacers comprise doped polysilicon.

25. A non-volatile memory array, comprising:
a substrate;
a plurality of gate structures arranged in rows and columns, each comprising
a gate dielectric layer on the substrate;
a gate on the gate dielectric layer;
two L-shaped trapping layers on sidewalls of the gate and the substrate; and
two conductive spacers on the sidewalls of the gate, separated from the gate and the substrate by the two L-shaped trapping layers;
a plurality of buried drains, each between two columns of gate structures; and
a plurality of word lines over the substrate, each contacting with the two conductive spacers and top of the gate of each of the gate structures in one row.

26. The non-volatile memory array of claim 25, wherein each L-shaped trapping layer comprises an ONO composite layer.

27. The non-volatile memory array of claim 25, wherein the gate dielectric layer comprises an oxide layer.

28. The non-volatile memory array of claim 25, wherein the word lines, the gates and the conductive spacer comprise doped polysilicon.
